(19) United States
(12) Patent Application Publication
(10) Pub. No.: US 2008/0116953 A1
(43) Pub. Date: May 22, 2008

(54) FLIP-FLOP CIRCUIT

(76) Inventors: Akio Hirata, Kyoto (JP); Hiroyuki Shinbo, Osaka (JP)

Correspondence Address: MCDERMOTT WILL & EMERY LLP, 600 13TH STREET, NW, WASHINGTON, DC, 20005-3096, US

(21) Appl. No.: 11/943,059

(22) Filed: Nov. 20, 2007

(30) Foreign Application Priority Data
Nov. 20, 2006 (JP) 2006-313007

(51) Int. Cl. H03K 3/012

(52) U.S. Cl. 327/218

(57) ABSTRACT

1. A flip-flop circuit including:
a pulse generation circuit that receives a clock signal and outputs an internal clock signal; and
a latch circuit,
   wherein the latch circuit includes:
an input section that receives a data signal and the internal clock signal, outputs a signal of a second logic level to a first node when the internal clock signal is at a first logic level, and outputs a signal of logic depending on a logic level of the data signal to the first node after the internal clock signal changes from the first logic level to the second logic level;
a control section that outputs a signal of the second logic level to a second node when the internal clock signal is at the first logic level, and outputs a signal of logic depending on a logic level of the first node to the second node when the internal clock signal is at the second logic level; and
an output section that outputs a signal of logic depending on a logic level of the first node and/or a logic level of the second node, and
   wherein the pulse generation circuit changes the internal clock signal from the first logic level to the second logic level in response to a change of the clock signal from a third logic level to a fourth logic level and changes the internal clock signal from the second logic level to the first logic level in response to a change of the first node or the second node from the second logic level to the first logic level.

### CROSS REFERENCE TO RELATED APPLICATIONS

This non-provisional application claims priority based on Patent Application No. 2006-313007 filed in Japan on Nov. 20, 2006, the entire contents of which are hereby incorporated by reference.

### BACKGROUND OF THE INVENTION

1. Technical Field

The present invention relates to a flip-flop circuit referred to as a pulse latch circuit.

2. Related Art

The proportion of a flip-flop circuit in the area, power consumption, and critical path delay of a logic circuit of a semiconductor integrated circuit is large and hence there is an increasing demand for a reduction in the area, a reduction in the power consumption, and a speedup of the flip-flop circuit.

A flip-flop circuit using a latch circuit that takes in data within a period of a pulse width shorter than a clock period has been proposed for high-speed use. An example in the related art of a flip-flop circuit having this construction will be described below.

FIG. 16 shows a general construction example of a flip-flop referred to as a pulse latch circuit. A reference symbol 1000 denotes a pulse latch circuit, 1100 denotes a pulse generation circuit, 1200 denotes a latch circuit, CK denotes a clock signal, D denotes a data signal, Q denotes an output signal, ICK denotes an internal clock signal, P1 and P2 denote p-type MOS (metal oxide semiconductor) transistors, N1 to N4 denote n-type MOS transistors, INV1 to INV7 denote inverter circuits, and ND1 denotes a NAND circuit.

The latch circuit 1200 keeps the output signal Q when the internal clock signal ICK is at a low level, and changes the output signal Q according to the data signal D when the internal clock signal ICK is at a high level.

The pulse generation circuit 1100 generates a pulse signal of a short width as the internal clock signal ICK when the clock signal CK rises up. When the clock signal CK is at the low level, the internal clock signal ICK is at the low level, and when the clock signal CK changes from the low level to the high level, the clock signal CK and a signal generated by reversing the clock signal CK after delay times of the inverter circuits INV4, INV5, and INV6 are inputted to the NAND circuit ND1. With this, a pulse signal of a width depending on the delay times of the inverter circuits INV4, INV5, and INV6 is generated.

In this manner, in the pulse latch circuit 1000, the width of the pulse signal is determined not by the operation of the latch circuit 1200 by the delay times of the inverter circuits INV4, INV5, and INV6. For this reason, when the width of the pulse signal is too short as compared with the operating time of the latch circuit 1200, data cannot be taken in. On this account, when the width of the pulse signal is changed by variations in manufacture, a power source voltage, and an ambient temperature, there is a possibility that the width of the pulse signal will become too short and hence the latch circuit 1200 will be unable to take in data, thereby causing a malfunction, or that contrarily, the width of the pulse signal will become too long and hence the latch circuit 1200 will cause a hold error. A pulse generation circuit shown in “patent document 2” is a circuit that changes the width of the pulse according to the weight of load driven by a pulse generation circuit and that does not guarantee that a latch circuit surely takes in data.

FIG. 17 is a flip-flop circuit disclosed in “non-patent document 1” and “patent document 1”. In FIG. 17, a reference symbol 2000 denotes a flip-flop circuit, D denotes a data signal, CK denotes a clock signal, Q denotes an output signal, IQ denotes an internal output signal, NQ denotes an output signal, and X1 and X2 denote nodes. The flip-flop circuit 2000 is constructed so as to include n-type MOS transistors N1 to N5, p-type MOS transistors P1 to P4, and inverter circuits INV1 to INV6.

In this circuit, the nodes X1 and X2 are pre-charged to a high level in a period during which the clock signal CK is at a low level. When the clock signal CK changes from the low level to the high level, if the data signal D is at the low level, the node X2 changes from the high level to the low level and the output signal NQ becomes the high level. When the clock signal CK changes from the low level to the high level, if the data signal D is at the high level, the node X1 changes from the high level to the low level and the output signal NQ becomes the low level.

However, when the clock frequency becomes high, the period during which the clock signal CK is at the low level becomes short. Thus, to shorten the time required to pre-charge the nodes X1 and X2, the gate sizes of the p-type MOS transistors P1 and P3 need to be made large. For this reason, the capacitance of a terminal to which the clock signal CK is inputted is made large, which in turn increases power consumption. Moreover, the size of a preceding clock buffer for outputting the clock signal CK need to be made large, which in turn further increases power consumption. In general, a clock signal is generated by a PLL and is inputted to a flop-flop circuit through a clock tree. The period during which the clock signal CK inputted to the flip-flop circuit is at the low level is changed by PLL, structure of the clock tree, variations in manufacture, age deterioration, and variations in the power source voltage and in the ambient temperature. Thus, in consideration of these variations, to make the flip-flop circuit operate even under the worst conditions, the gate sizes of the p-type MOS transistors P1 and P3 for pre-charging the node X1 and X2 need to be set to larger sizes.

Moreover, each of circuits disclosed in “patent document 3” and “patent document 4” compares the level of a data signal with the level of an output signal and generates a pulse only when both of the levels are different from each other. The width of the pulse is determined after detecting that a latch circuit finishes taking in data, so the latch circuit does not fail in taking in the data. However, the comparing of the data signal with the output signal causes a delay time, so the data signal needs to arrive before the clock signal changes. Hence, this presents a problem that a set-up time limit is increased to make it difficult to operate the flip-flop circuit at high speed.

As described hereinbefore, in the flip-flop circuit in the related art, it is difficult to realize the compatibility between a stable operation without a malfunction for variations in manufacture, age deterioration, variations in a power source voltage and in an ambient temperature and an operation at high speed and at low power consumption.

### [Patent document 1] Japanese Unexamined Patent Publication No. 2004-159315

[Patent document 2] Specification of U.S. Pat. No. 6,661,121
[Patent document 3] Japanese Unexamined Patent Publication No. Hei 10-290142

### [Patent document 4] Japanese Unexamined Patent Publication No. 2000-232339

### [Non-patent document 1] AKIO HIRATA et al., “The Cross Charge-control Flip-Flop: a Low-Power and High-speed Flip-Flop Suitable for Mobile Application SoCs”, 2005 Symposium On VLSI Circuit, pp. 306-307

### SUMMARY OF THE INVENTION

As described above, a flip-flop circuit in the related art is hard to use at a high clock frequency or is hard to operate stably without a malfunction when variations in manufacture, age deterioration, and variations in a power source voltage and in an ambient temperature occur.

The object of the present invention is to provide a flip-flop circuit that can stably operate without a malfunction even when variations in manufacture, age deterioration, and variations in a power source voltage and in an ambient temperature occur and can operate at a high clock frequency and at low power consumption.

A flip-flop circuit according to the present invention includes a latch circuit and a pulse generation circuit. The latch circuit includes an input section, a control section, and an output section.

The input section receives one or plural data signals and an internal clock signal, outputs a signal of a second logic level to a first node when the internal clock signal is at a first logic level, and outputs a signal of logic depending on a data signal to the first node after the internal clock signal changes from the first logic level to the second logic level.

The control section outputs a signal of the second logic level to a second node when the internal clock signal is at the first logic level, and outputs a signal depending on the first node to the second node when the internal clock signal is at the second logic level.

The output section outputs a group of signals depending on a signal of the first node and/or a signal of the second node.

The pulse generation circuit outputs a signal changing from the first logic level to the second logic level to the internal clock signal when a clock signal changes from a third logic level to a fourth logic level, and outputs a signal changing from the second logic level to the first logic level to the internal clock signal when a signal of the first node or a signal of the second node changes from the second logic level to the first logic level.

With this construction, the internal clock signal is made a pulse signal of a width shorter than a period of the clock signal and the period during which the first node and the second node are pre-charged can be elongated and an operation at a high clock frequency can be performed. Alternatively, the size of a MOS transistor for pre-charging the first node and the second node can be reduced and hence power consumption can be reduced. Moreover, since the width of the pulse changes in good agreement with the operations of the first node and the second node, the flip-flop circuit stably operates without a malfunction even when variations in manufacture, age deterioration, variations in the power source voltage and in the ambient temperature occur.

Further, the pulse generation circuit includes a racing prevention mechanism that keeps the internal clock signal at the first logic even if after the pulse generation circuit outputs a signal changing from the first logic level to the second logic level to the internal clock signal when a clock signal changes from a third logic level to a fourth logic level and outputs a signal changing from the second logic level to the first logic level to the internal clock signal when a signal of the first node or a signal of the second node changes from the second logic level to the first logic level, a signal of the first node or a signal of the second node changes again from the first logic level to the second logic level in a period during which the clock signal is at the fourth level. With this, a malfunction can be further prevented.

Further, the absolute value of the threshold voltage of a first-conduction type MOS transistor for pre-charging the first and second nodes is relatively made smaller than the absolute value of the threshold voltage of the other MOS transistor.

With this, an operation at a higher clock frequency can be performed or the size of a gate of the MOS transistor can be reduced and hence power consumption can be reduced. In the construction of the present invention, the period during which the first-conduction type MOS transistor for pre-charging the first and second nodes is OFF is the period of the pulse width of the internal clock signal and hence is short. Thus, even if the absolute value of the threshold voltage is made small, an increase in the leak current of the flip-flop circuit is small, which does not become a problem.

Another flip-flop circuit according to the present invention includes: a pulse generation circuit that receives a clock signal and outputs an internal clock signal; and a plurality of latch circuits.

Each of the plurality of latch circuits includes:

an input section that receives a data signal and the internal clock signal, outputs a signal of a second logic level to a first node when the internal clock signal is at a first logic level, and outputs a signal of logic depending on a logic level of the data signal to the first node after the internal clock signal changes from the first logic level to the second logic level;

a control section that outputs a signal of the second logic level to a second node when the internal clock signal is at the first logic level, and outputs a signal of logic depending on a logic level of the first node to the second node when the internal clock signal is at the second logic level; and

an output section that outputs a signal of logic depending on a logic level of the first node and/or a logic level of the second node.

The pulse generation circuit changes the internal clock signal from the first logic level to the second logic level in response to a change of the clock signal from a third logic level to a fourth logic level and changes the internal clock signal from the second logic level to the first logic level after the first node or the second node changes from the second logic level to the first logic level in all of the plurality of latch circuits.

According to the present invention, the flip-flop circuit can operate at a higher clock frequency or can reduce power consumption and at the same time can reduce the number of transistors by the sharing of the pulse generation circuit and can reduce the chip area of the semiconductor integrated circuit.

The flip-flop circuit of the present invention can operate stably without a malfunction for variations in manufacture, and variations in power source voltage and ambient temperature and can operate at a high clock frequency and at low power consumption.

### BRIEF DESCRIPTION OF THE DRAWINGS

FIG. 1 is a circuit diagram of a flip-flop circuit according to a first embodiment of the present invention.

FIG. 2 is a timing chart showing an operation of the flip-flop circuit shown in FIG. 1.

FIGS. 3 to 9 are construction examples of a pulse generation circuit.

FIG. 10 is a timing chart showing an operation of the flip-flop circuit using the pulse generation circuits shown in FIGS. 7 to 9.

FIGS. 11 and 12 are construction examples of a latch circuit.

FIG. 13 is a circuit diagram of a flip-flop circuit according to a second embodiment of the present invention.

FIG. 14 is a circuit diagram of a flip-flop circuit according to a third embodiment of the present invention.

FIG. 15 is a layout diagram of the flip-flop circuit according to the third embodiment of the present invention.

FIG. 16 is a circuit diagram of a pulse latch circuit in a related art.

FIG. 17 is a circuit diagram of a flip-flop circuit in a related art.

### DESCRIPTION OF THE PREFERRED EMBODIMENTS

The embodiments of the present invention will be described below with reference to the drawings.

### First Embodiment

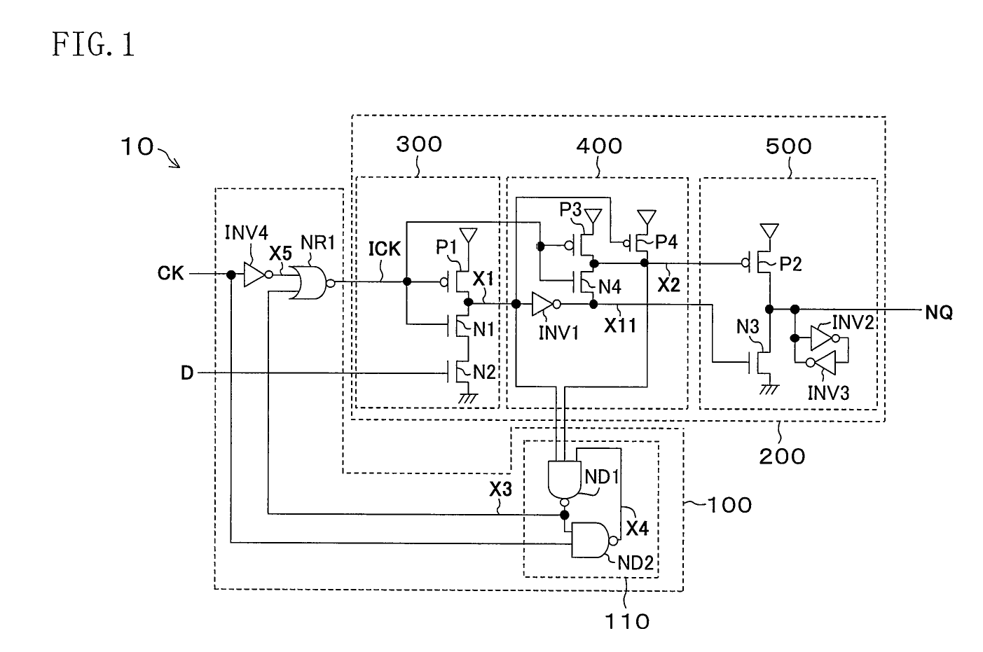

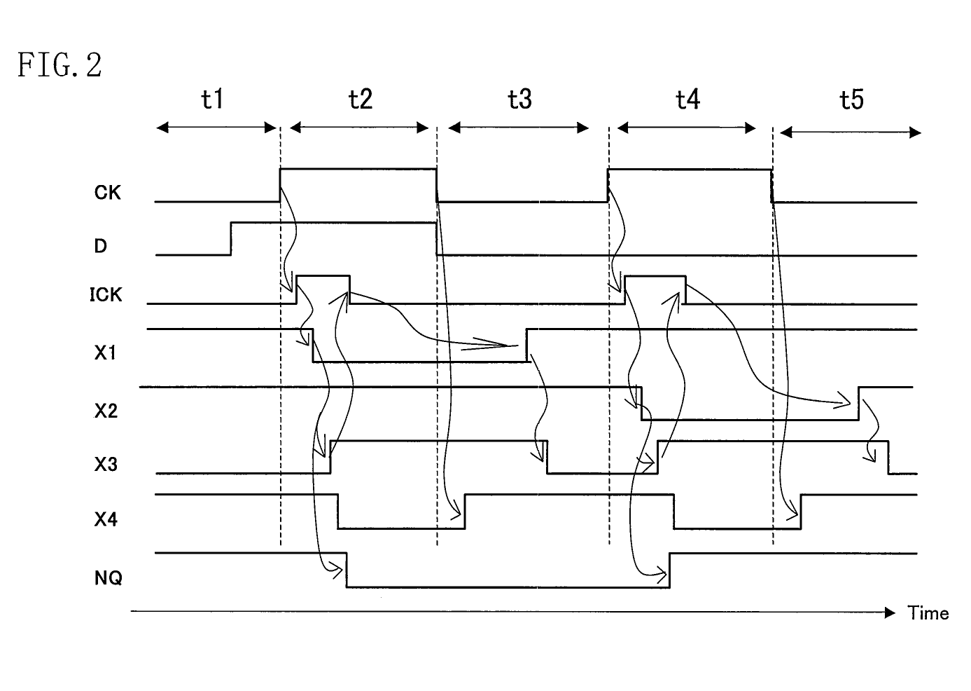

FIG. 1 is a circuit diagram showing a flip-flop circuit according to a first embodiment and FIG. 2 is a timing chart showing its operation.

A reference symbol 100 denotes a pulse generation circuit, 200 denotes a latch circuit, 300 denotes an input section, 400 denotes a control section, 500 denotes an output section, 110 denotes a racing prevention mechanism, INV1 to INV4 denote inverter circuits, ND1 and ND2 denote NAND circuits, P1 to P4 denote p-type MOS transistors, and N1 to N4 denote n-type MOS transistors. X1 to X5 and X1 denote nodes. A reference symbol CK denotes a clock signal inputted to a clock terminal, ICK denotes an internal clock signal, D denotes a data signal inputted to a data input terminal, and NQ denotes an output signal outputted from an output terminal.

When the internal clock signal ICK is at a low level, the input section 300 outputs a high-level signal to the node X1 irrespective of the value of the data signal D. When the internal clock signal ICK is at a high level, if the data signal D is at a high level, the input section 300 outputs a low-level signal to the node X1 and if the data signal D is at a low level, the input section 300 keeps the signal level of the node X1.

The control section 400 outputs a reverse signal of the signal of the node X1 to the node X11. When the internal clock signal ICK is at the low level, the control section 400 outputs a high-level signal to the node X2 and when the internal clock signal ICK is at the high level, the control section 400 outputs a signal of the same level as the node X11 to the node X2.

When the node X1 is at the low level and the node X2 is at the high level, the output section 500 keeps the value of the output signal NQ. When the node X11 is at the high level and the node X2 is at the high level, the output section 500 outputs a low-level signal to the output signal NQ. When the node X11 is at the low level and the node X2 is at the low level, the output section 500 outputs a high-level signal to the output signal NQ.

When the clock signal CK is at the low level, the pulse generation circuit 100 outputs a high-level signal to the nodes X4 and X5 and outputs a low-level signal to the internal clock signal ICK. At this time, both of the internal nodes X1 and X2 are at the high level and hence the node X3 becomes the low level. When the clock signal CK changes from the low level to the high level, the node X5 becomes the low level and the internal clock signal ICK changes from the low level to the high level. At this time, if the data signal D is at the high level, the signal of the node X1 changes from the high level to the low level, and if the data signal D is at the low level, the signal of the node X2 changes from the high level to the low level. With this, the NAND circuit ND1 has the low level signal added to either the node X1 or the node X2 which is an input, so the NAND circuit ND1 outputs a high-level signal to the node X3. At this time, both of the node X3 and the clock signal CK, which are inputs, become the high level, and hence the NAND circuit ND2 outputs a low-level signal to the node X4. The node X3 changes to the high level and then the internal clock signal ICK, which is the output of an NOR circuit NR1, changes from the high level to the low level. With this, the nodes X1 and X2 again change to the high level. At this time, since the node X4 is at the low level, the node X3 is held at the high level. In this manner, by using the NAND circuits ND1 and ND2 in combination, a mechanism for preventing the racing of the internal clock signal ICK is constructed.

Next, the operation of the flip-flop circuit shown in FIG. 1 will be described with reference to FIG. 2.

First, let's consider a case where the clock signal CK is at the low level (period t1 in FIG. 2). At this time, the internal clock signal ICK is at the low level and the p-type MOS transistors P1, P3 turns ON, and hence the nodes X1, X2 become the high level. The node X4 becomes the high level and the node X3 becomes the low level.

Let's consider a case where when the clock signal CK changes from the low level to the high level, the input signal D is at the high level (period t2 in FIG. 2). The internal clock signal ICK changes from the low level to the high level and the p-type MOS transistor P1 turns OFF and both of the n-type MOS transistors N1, N2 turn ON, and hence the node X1 changes from the high level to the low level. With this, the node NQ changes from the high level to the low level and the node X3 changes from the low level to the high level and the internal clock signal ICK again changes from the high level to the low level. With this, the p-type MOS transistor P1 turns ON and the n-type MOS transistor N1 turns OFF, and hence the node X1 again changes to the high level.

Next, when the clock signal CK changes from the high level to the low level (period t3 in FIG. 2), the node X4 changes from the low level to the high level and both of the nodes X4 and X1 change to the high level and then the node X3 changes from the high level to the low level.

Let's consider a case where when the clock signal CK changes from the low level to the high level, the input signal D is at the low level (period t4 in FIG. 2). The internal clock signal ICK changes from the low level to the high level. The node X1 is held at the high level and the node X11 to which its reverse output is connected is at the low level. Because the p-type MOS transistor P3 is OFF and the n-type MOS transistor N4 is ON and the node X11 is at the low level, the node X2 changes from the high level to the low level. With this, the output signal NQ changes from the low level to the high level and the node X3 changes from the low level to the high level and the internal clock signal ICK again changes from the high level to the low level. With this, the p-type MOS transistor P2 turns ON and the n-type MOS transistor N4 turns OFF, and hence the node X2 again changes to the high level.

Next, when the clock signal CK changes from the high level to the low level (period t5 in FIG. 2), the node X4 changes from the low level to the high level and both of the node X4 and X2 change to the high level and then the node X3 changes from the high level to the low level.

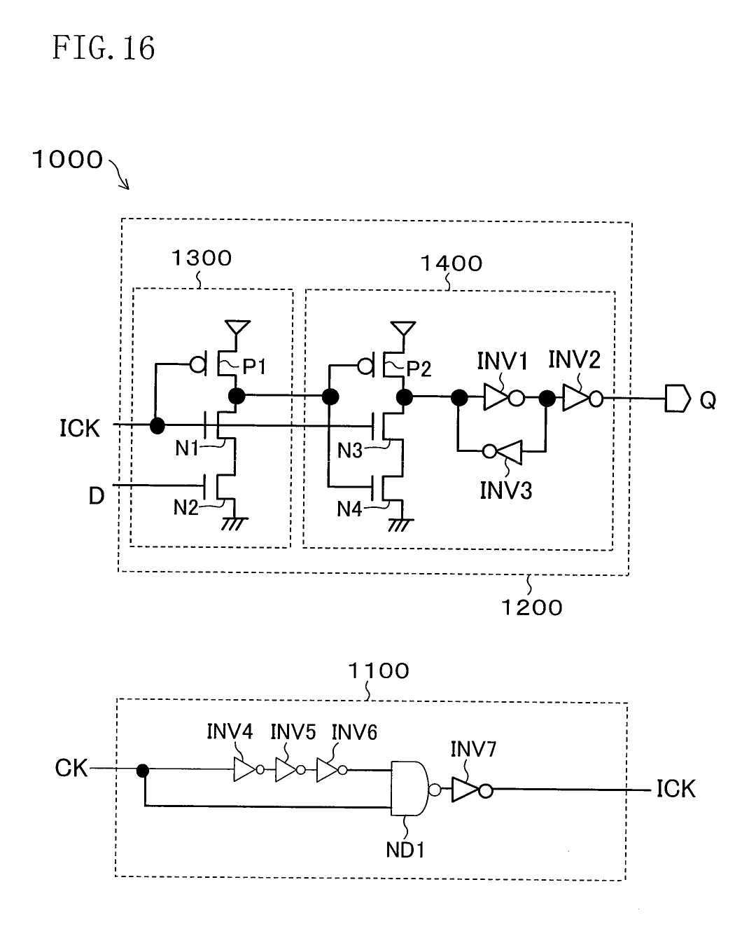

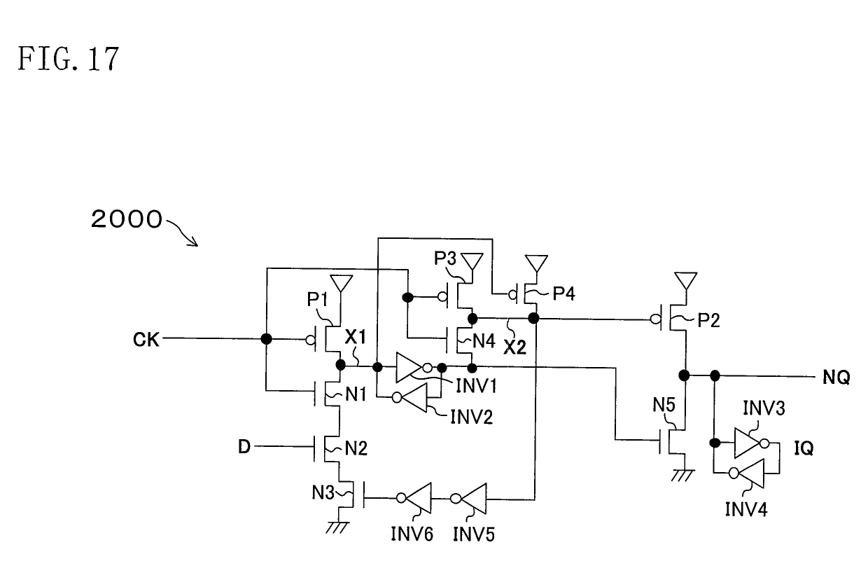

Here, although the time required for the signal to change is neglected (is considered to be zero) in FIG. 2 for convenience, in reality, the signal changes gradually. If the nodes X1 and X2 are not electrically charged to a sufficient power source voltage level (for example, 95% or more of a power source voltage) before the internal clock signal ICK falls down and then again rises up, a malfunction is caused. The period during which the nodes X1 and X2 are electrically charged is the period during which the internal clock ICK is at the low level in this embodiment and is the period during which the clock signal CK is at the low level (t1, t2, and t3) in a conventional circuit shown in FIG. 16. As is evident from FIG. 2, the period during which the internal clock ICK is at the low level is longer than the period during which the clock signal CK is at the low level. Hence, according to this embodiment, the period of time during which the nodes X1 and X2 are electrically charged can be made longer than in the conventional circuit shown in FIG. 16. Thus, if the sizes of the p-type MOS transistors for charging the nodes X1, X2 (P1 and P3 in FIG. 1 and FIG. 16) in this embodiment are the same as those in the conventional circuit, the p-type MOS transistors in this embodiment can operate at a higher clock frequency (=a reciprocal of a clock cycle time). Moreover, in the operation of the same clock frequency, the sizes of the p-type MOS transistors P1 and P3 for charging the nodes X1 and X2 can be made smaller in this embodiment than in the conventional circuit, and hence power consumption can be further reduced in this embodiment.

Moreover, the pulse width of the internal clock signal ICK changes according to II the operation of the nodes X1 and X2, and hence even if variations in manufacture, aged deterioration, and variations in the power source voltage and in the ambient temperature occur, the flip-flop circuit operates stably without a malfunction.

As described hereinbefore, according to the first embodiment of the present invention, it is possible to realize a flip-flop circuit that can stably operate without a malfunction for variations in manufacture, aged deterioration, and variations in the power source voltage and in the ambient temperature and operates at a high clock frequency and is low in power consumption.

Although a construction example using the MOS transistors has been described here, a transistor using an insulating film other than an oxide film may be used. This is ditto for the following embodiments.

### (Another Construction Example of Pulse Generation Circuit 100)

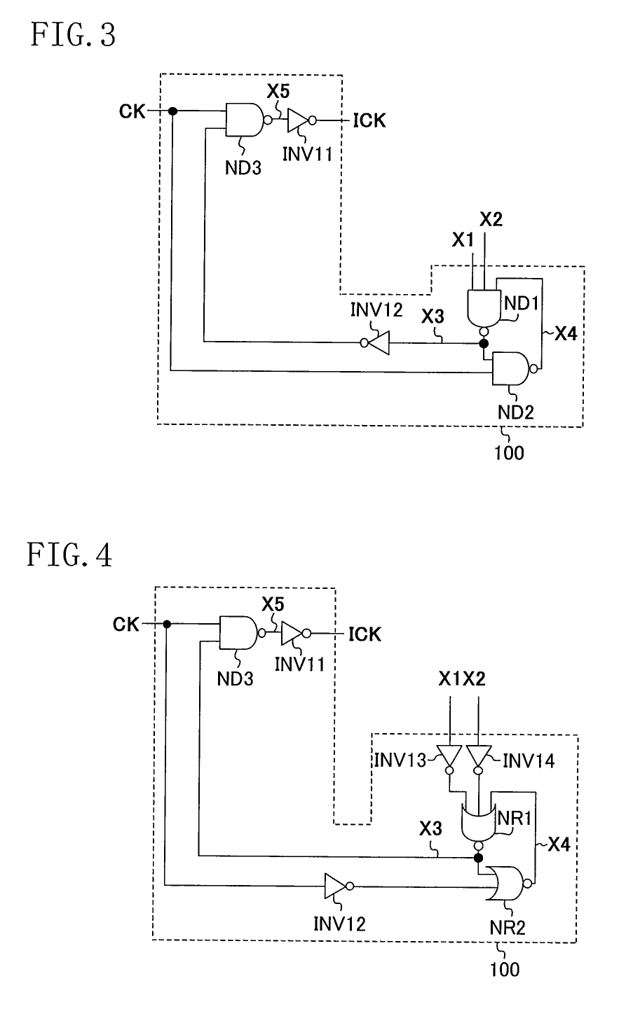

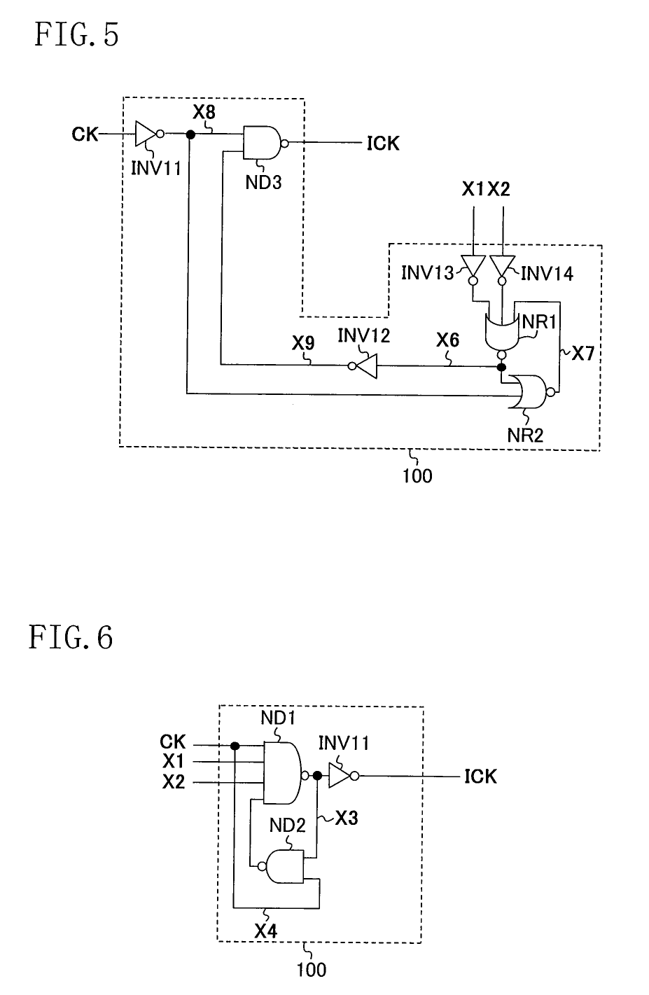

Another construction example of the pulse generation circuit 100 is shown in FIG. 3 to FIG. 6. Reference symbols ND1 to ND3 denote NAND circuits, NR1 and NR2 denote NOR circuits, INV11 to INV14 denote inverter circuits, and X1 to X9 denote nodes. A reference symbol CK denotes a clock signal inputted to a clock terminal, and ICK denotes an internal clock signal. This construction is different from the pulse generation circuit 100 shown in FIG. 1 in an internal circuit construction, but the operation of the internal clock signal ICK to be outputted for the operations of the clock signal CK and the nodes X1 and X2, which are the input signals, in this construction is the same as that in the pulse generation circuit 100 shown in FIG. 1.

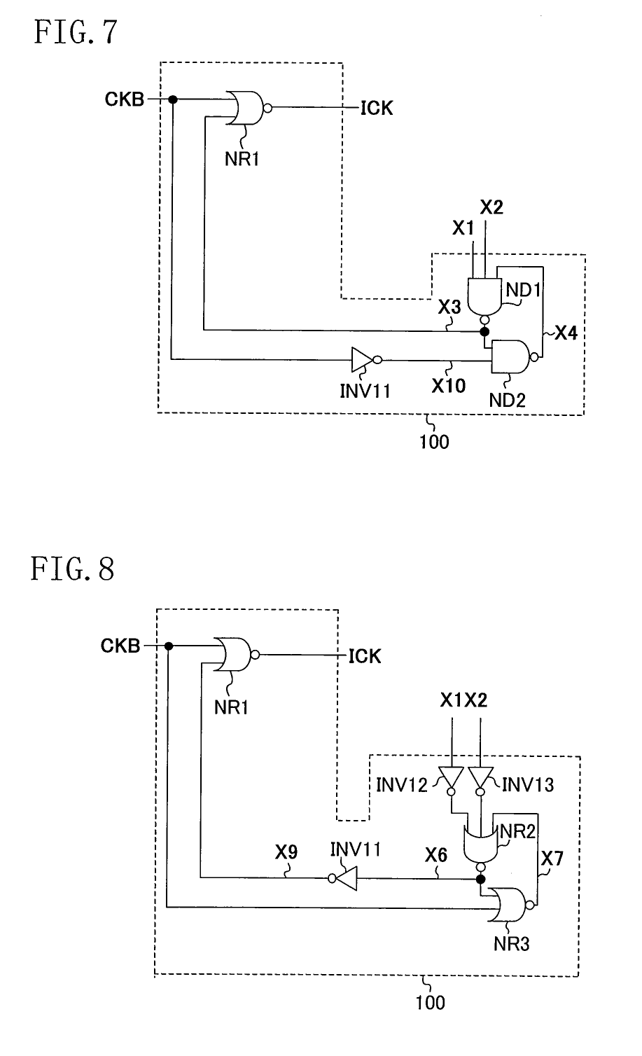

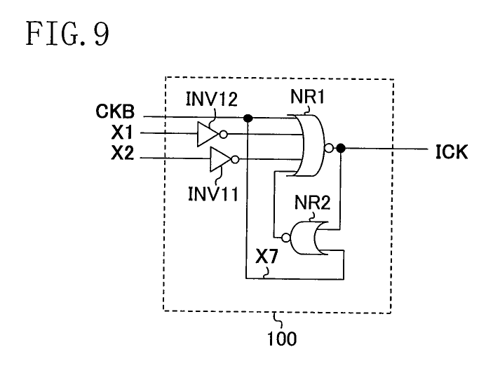

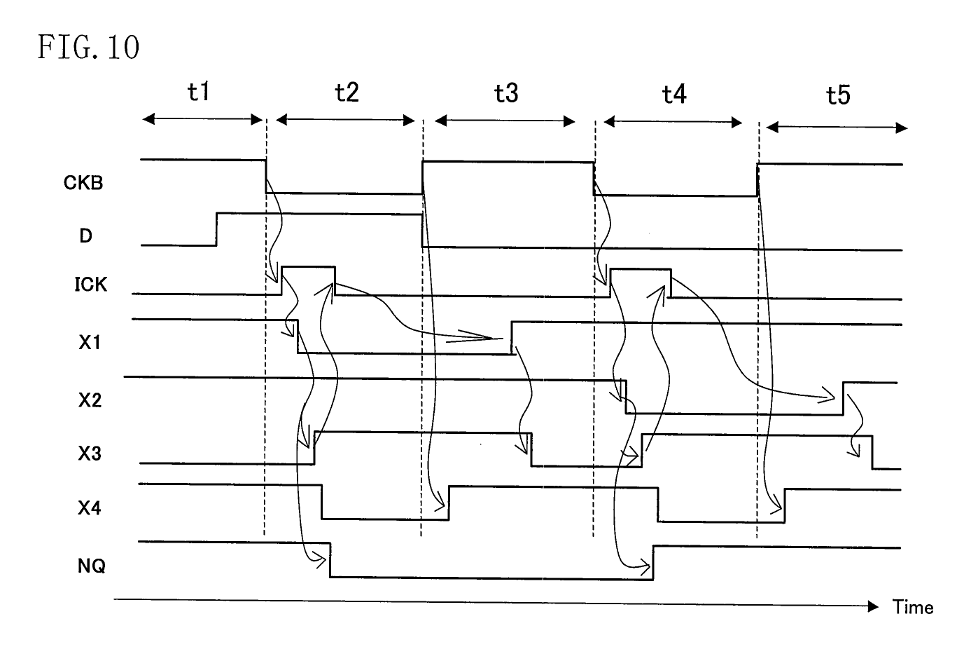

Still another construction example of the pulse generation circuit 100 is shown in FIG. 7 to FIG. 9. Reference symbols ND1 and ND2 denote NAND circuits, NR1 to NR3 denote NOR circuits, INV11 to INV13 denote inverter circuits, and X1 to X4, X6, X7, X9 and X10 denote nodes. A reference symbol CKB denotes a clock signal inputted to a clock terminal, and ICK denotes an internal clock signal. In the pulse generation circuit 100 shown in FIG. 7 to FIG. 9, the polarity of the clock signal is reversed as compared with the pulse generation circuit 100 shown in FIG. 1 and FIG. 3 to FIG. 6. In other words, in the case where the pulse generation circuit 100 shown in FIG. 7 to FIG. 9 is used, when the clock signal CKB falls down, the flip-flop circuit 10 takes in a data signal D. Its operation is shown in a timing chart shown in FIG. 10. Operations of the signals in this timing chart shown in FIG. 10 are the same as those in the timing chart shown in FIG. 2 except that the clock signal CKB in FIG. 10 is reverse to the clock signal CK in FIG. 2. To generate the internal clock signal ICK, in the pulse generation circuit shown in FIG. 3 to FIG. 6, two logic circuits are required to be arranged between the clock signal CK and the internal clock signal ICK, but in the pulse generation circuit shown in FIG. 7 to FIG. 9, it suffices to arrange one logic circuit. Thus, a delay time that passes after the clock signal CKB changes until the output signal NQ changes can be decreased.

### (Another Construction Example of Latch Circuit 200)

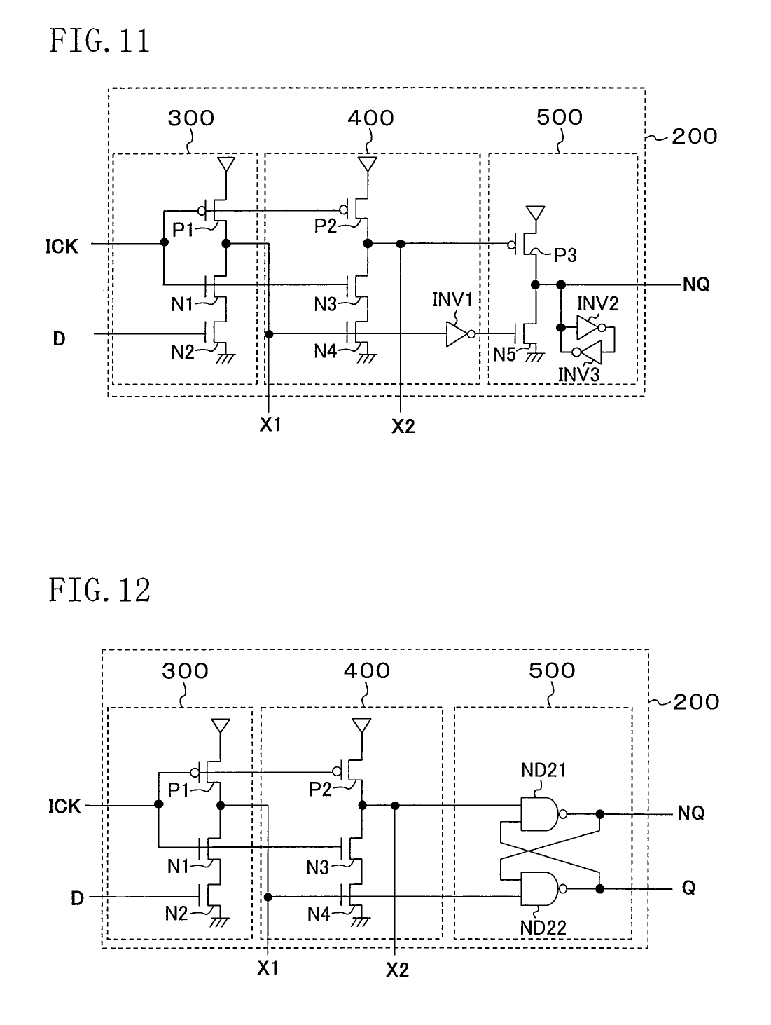

Another construction example of the latch circuit 200 is shown in FIG. 11 to FIG. 12. A reference symbol 200 denotes a latch circuit, 300 denotes an input section, 400 denotes a control section, 500 denotes an output section, INV1 to INV3 denote inverter circuits, ND21 and ND22 denote NAND circuits, P1 to P3 denote p-type MOS transistors, N1 to N5 denote n-type MOS transistors, and X1 to X2 denote nodes. A reference symbol ICK denotes an internal clock signal, D denotes a data signal inputted to a data input terminal, and Q and NQ denote output signals outputted from output terminals.

The latch circuit 200 shown in FIG. 11 is different from the latch circuit 200 shown in FIG. 1 in the internal circuit construction but is the same as the latch circuit 200 shown in FIG. 1 in the operations of the output signal NQ and the nodes X1, X2 which are outputted in response to the operations of the internal clock signal ICK and the data input signal D which are input signals.

Moreover, the latch circuit 200 shown in FIG. 12 is different from the latch circuit 200 shown in FIG. 1 in the internal circuit construction but is the same as the latch circuit 200 shown in FIG. 1 in the operations of the output signal NQ and the nodes X1, X2 which are outputted in response to the operations of the internal clock signal ICK and the data input signal D which are input signals. Here, the output signal Q is reverse to the output signal NQ.

In any one of a case where any one of the pulse generation circuits 100 shown in FIG. 3 to FIG. 9 is applied to the flip-flop circuit 10 shown in FIG. 1, a case where either of the latch circuits 200 shown in FIG. 11 and FIG. 12 is applied to the flip-flop circuit 10 shown in FIG. 1, and a case where any one of the pulse generation circuits 100 shown in FIG. 3 to FIG. 9 and either of the latch circuits 200 shown in FIG. 11 and FIG. 12 are applied to the flip-flop circuit 10 shown in FIG. 1, just as with the case described above, the flip-flop circuit 10 shown in FIG. 1 can operate at a higher clock frequency or at lower power consumption than in the related art.

### Second Embodiment

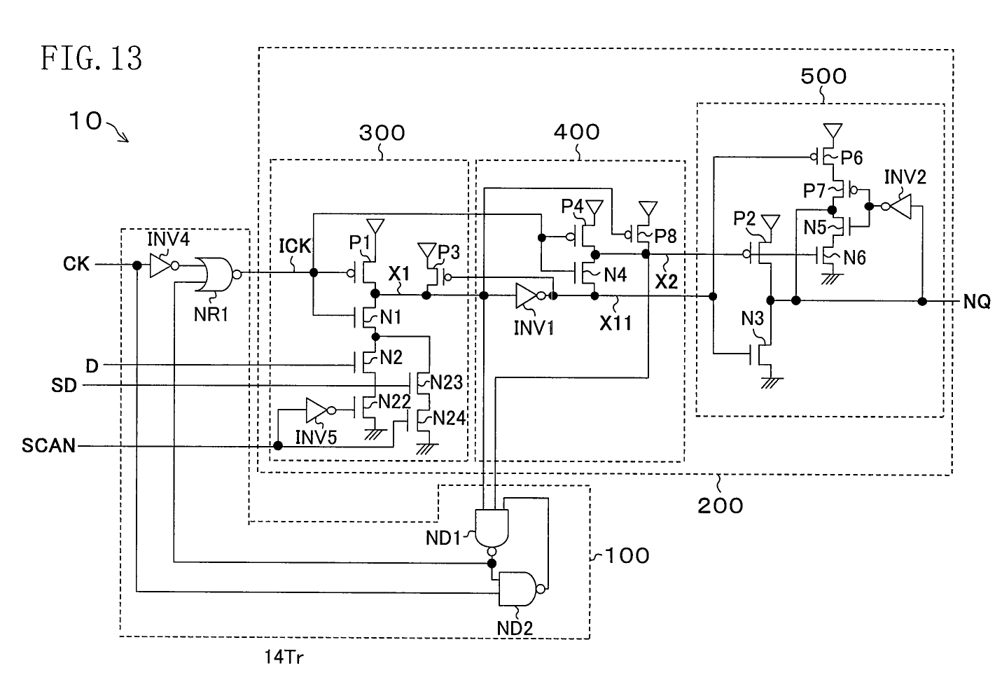

FIG. 13 is a circuit diagram showing a flip-flop circuit according to a second embodiment.

A reference symbol 100 denotes a pulse generation circuit, 200 denotes a latch circuit, 300 denotes an input section, 400 denotes a control section, 500 denotes an output section, INV1 to INV4 denote inverter circuits, ND1 and ND2 denote NAND circuits, P1 to P4 denote p-type MOS transistors, and N1 to N4 and N22 to N24 denote n-type MOS transistors. Reference symbols X1 to X5 and X1 denote nodes. A reference symbol CK denotes a clock signal inputted to a clock terminal, ICK denotes an internal clock signal, D denotes a data signal inputted to a data input terminal, SD denotes a scanning data signal inputted to a scanning data input terminal, SCAN denotes a scanning selection signal inputted to a scanning selection terminal, and NQ denotes an output signal outputted from an output terminal.

When the scanning selection signal SCAN is at the low level, the flip-flop circuit 10 outputs a signal depending on the data signal D to the output signal NQ when the clock signal CK rises up, and when the scanning selection signal SCAN is at the high level, the flip-flop circuit 10 outputs a signal depending on the scanning data signal SD to the output signal NQ when the clock signal CK rises up. Moreover, to make a scanning construction, the flip-flop circuit 10 of this embodiment has the n-type MOS transistors N22, N23, and N24 and the inverter circuit INV 5 added thereto and has the p-type MOS transistors P3, P6 and the n-type MOS transistor N6 added thereto, as compared with the flip-flop circuit 10 of the first embodiment shown in FIG. 1.

Next, the operation of the flip-flop circuit 10 shown in FIG. 13 will be described.

When the internal clock signal ICK is at the low level, the input section 300 outputs a high-level signal to the node X1 irrespective of the value of the data signal D and the scanning data signal SD. When the internal clock signal ICK is at the high level and the scanning selection signal SCAN is at the low level, if the data signal D is at the high level, the input section 300 outputs a low-level signal to the node X1, and if the data signal D is at the low level, the input section 300 keeps the signal level of the node X1. When the internal clock signal ICK is at the high level and the scanning selection signal SCAN is at the high level, if the scanning data signal SD is at the high level, the input section 300 outputs a low-level signal to the node X1, and if the scanning data signal SD is at the low level, the input section 300 keeps the signal level of the node X1. The p-type MOS transistor P3 prevents the electric potential of the node X1 from being lowered by the effect of sharing charge with the capacitance of a source terminal when the n-type MOS transistor N1 turns ON when the internal clock signal ICK changes from the low level to the high level, thereby preventing the occurrence of a malfunction.

The control section 400 outputs a signal which is reverse to the signal of the node X1 to the node X1. When the internal clock signal ICK is at the low level, the control section 400 outputs a high-level signal to the node X2, and when the internal clock signal ICK is at the high level, the control section 400 outputs a signal of the same level as the node X1 to the node X2.

When the node X1 is at the low level and the node X2 is at the high level, the output section 500 keeps the value of the output signal NQ. When the node X2 is at the high level and the node X11 is at the high level, the output section 500 outputs a low level signal to the output signal NQ. When the node X2 is at the high level and the node X11 changes from the low level to the high level, the p-type MOS transistor P6 turns OFF and hence prevents an extra through current from flowing when the output signal NQ changes from the high level to the low level. When the node X11 is at the low level and the node X2 is at the low level, the output section 500 outputs a high level signal to the output signal NQ. When the node X11 is at the low level and the node X2 changes from the high level to the low level, the n-type MOS transistor N6 turns OFF and hence prevents an extra through current from flowing when the output signal NQ changes from the low level to the high level.

As described above, the flip-flop circuit according to the second embodiment can perform the operation at a higher clock frequency or at lower power consumption also in the scanning construction than in the related art. Moreover, the additionally arranged p-type MOS transistor P3 can prevent the occurrence of a malfunction. Furthermore, the additionally arranged p-type MOS transistor P6 and n-type MOS transistor N6 can prevent an extra through current from flowing and can reduce power consumption.

In this regard, when the p-type MOS transistors (P1 and P3 shown in FIG. 1, P1 and P2 shown in FIG. 11 and FIG. 12, and P1 and P4 shown in FIG. 13) that changes the nodes X1, X2 from the low level to the high level in the flip-flop circuits according to the first and second embodiments are constructed of MOS transistors having a lower threshold voltage than the other MOS transistors, the flip-flop circuits can be operated at a higher clock frequency. In general, when the MOS transistor having a lower threshold voltage is used, power consumption is increased by an increase in leak current flowing when the MOS transistor is OFF state. However, the period during which the p-type MOS transistor is OFF state, that is, the period during which the internal clock signal ICK is at the high level is sufficiently shorter than the cycle time of the clock signal CK (period of (t2+t3) in FIG. 2), and hence an increase in the power consumption is small.

In this regard, the latch circuit of the present invention is not necessarily constructed in the manner shown in the first and second embodiments, but it suffices to construct the latch circuit in such a way that the latch circuit has two pre-charged nodes and discharges one of the two pre-charged nodes when the clock signal changes. For example, the latch circuit may be constructed in the manner of a sense amplifier.

### Third Embodiment

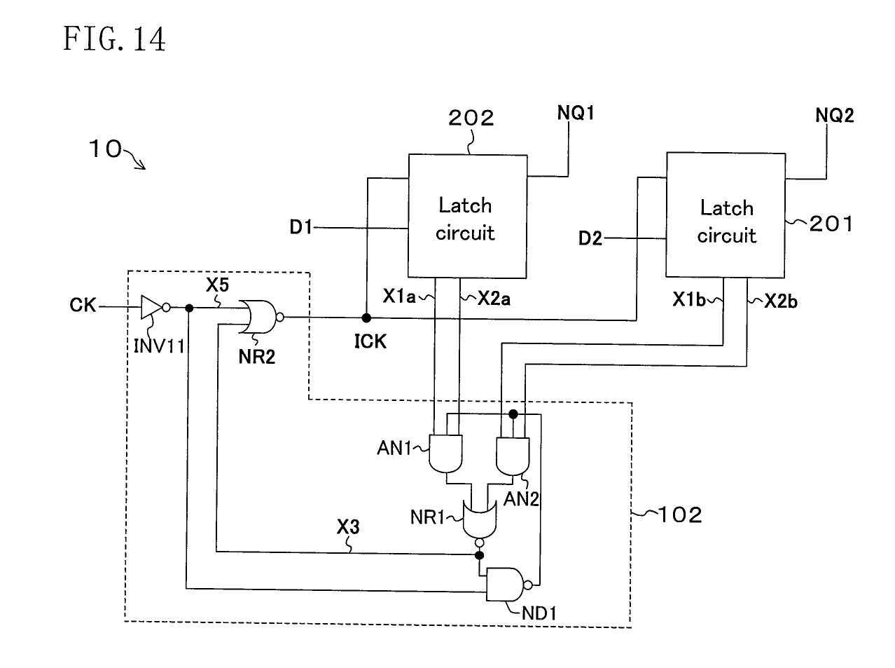

FIG. 14 is a circuit diagram showing a flip-flop circuit according to a third embodiment of the present invention.

A reference symbol 102 denotes a pulse generation circuit, 201, 202 denote latch circuits, INV11 denotes an inverter circuit, AN1 and AN2 denote AND circuits, ND1 denote a NAND circuit, NR1 and NR2 denote NOR circuits, CK denotes a clock signal inputted to a clock terminal, ICK denotes an internal clock signal, D1, D2 denote data signals inputted to data input terminals, NQ1, NQ2 denote output signals outputted to output terminals, and X1a, X1b, X2a, and X2b are nodes.

It suffices to use the same internal construction as shown in either of the first and second embodiments for the internal constructions of the latch circuits 201 and 202. The internal clock signal ICK rises up and then either the node X1a or the node X2a changes from the high level to the low level and either the node X1b or the node X2b changes from the high level to the low level.

The pulse generation circuit 102 lowers the internal clock signal ICK after the internal clock signal ICK rises up and then either the node X1a or the node X2a changes from the high level to the low level and either the node X1b or the node X2b changes from the high level to the low level.

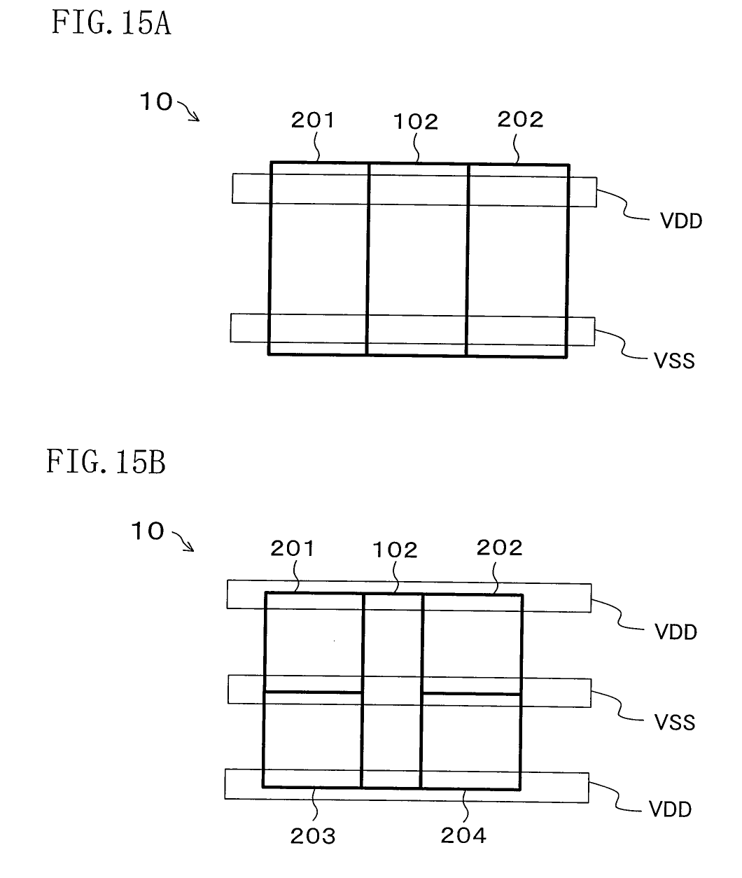

The layout diagram of the flip-flop circuit of this embodiment is shown in FIGS. 15A and 15B. A reference symbol 102 denotes a pulse generation circuit, 201 to 204 denote latch circuits, VDD denotes a power source line, and VSS denotes a grounding line. In FIG. 15A is shown an example such that one pulse generation circuit 102 is shared by two latch circuits 201, 202. The pulse generation circuit 102 is arranged in the middle of the latch circuits 201, 202 in such a way that the times required for the internal clock signals ICK to reach the latch circuits 201, 202 become equal to each other. Similarly, in FIG. 15B is shown an example such that one pulse generation circuit 102 is shared by four latch circuits 201 to 204. Here, in this example, the pulse generation circuit 102 is constructed in a double height (twice as high as an ordinary standard logic cell) but may be constructed in the height of an ordinary cell. In this case, the latch circuits 201 to 204 may be aligned laterally. Moreover, the examples such that one pulse generation circuit is shared by plural latch circuits have been shown here, but even if one pulse generation circuit is arranged for one latch circuit, it is preferable that the pulse generation circuit and the latch circuit are arranged next to each other so as to decrease the delay time of the internal clock signal.

According to this embodiment, just as with the first and second embodiments, the flip-flop circuit can be operated at a higher clock frequency or at lower power consumption than in the related art. In addition, by the shared use of the pulse generation circuit 102, it is possible to reduce the number of transistors and hence to reduce the chip area of a semiconductor integrated circuit.

### INDUSTRIAL APPLICABILITY

A flip-flop circuit according to the present invention operates stably without a malfunction even if variations in manufacture, age deterioration, and variations in the power source voltage and in the ambient temperature occur and operates at high speed and at low power consumption. Hence, the flip-flop circuit is usefully applicable to a semiconductor integrated circuit that is more sophisticated in functionality, needs to be reduced in power consumption, and is large in scale.

What is claimed is:

1. A flip-flop circuit comprising:
a pulse generation circuit that receives a clock signal and outputs an internal clock signal; and
a latch circuit,
wherein the latch circuit includes:
an input section that receives a data signal and the internal clock signal, outputs a signal of a second logic level to a first node when the internal clock signal is at a first logic level, and outputs a signal of logic depending on a logic level of the data signal to the first node after the internal clock signal changes from the first logic level to the second logic level;
a control section that outputs a signal of the second logic level to a second node when the internal clock signal is at the first logic level, and outputs a signal of logic depending on a logic level of the first node to the second node when the internal clock signal is at the second logic level; and
an output section that outputs a signal of logic depending on a logic level of the first node and/or a logic level of the second node, and
wherein the pulse generation circuit changes the internal clock signal from the first logic level to the second logic level in response to a change of the clock signal from a third logic level to a fourth logic level and changes the internal clock signal from the second logic level to the first logic level in response to a change of the first node or the second node from the second logic level to the first logic level.

2. The flip-flop circuit according to claim 1,
wherein the pulse generation circuit includes a racing prevention mechanism that keeps the internal clock signal at the first logic level even if the internal clock signal is changed from the second logic level to the first logic level and then the first node or the second node changes from the first logic level to the second logic level in a period during which the clock signal is at the fourth level.

3. The flip-flop circuit according to claim 1,
wherein the first logic level is equal to the third logic level and the second logic level is equal to the fourth logic level.

4. The flip-flop circuit according to claim 3,
wherein the pulse generation circuit includes:
a first NAND circuit that outputs a reverse logical product (NAND) of a logic level of the first node, a logic level of the second node, and a logic level of a fourth node to a third node;
a second NAND circuit that outputs a reverse logical product (NAND) of a logic level of the third node and the clock signal to the fourth node;
an inverter circuit that reverses logic of the clock signal and outputs the reversed clock signal to a fifth node; and
a NOR circuit that outputs a reverse logical sum (NOR) of a logic level of the third node and a logic level of the fifth node as the internal clock signal.

5. The flip-flop circuit according to claim 3,
wherein the pulse generation circuit includes:
a first NAND circuit that outputs a reverse logical product (NAND) of a logic level of the first node, a logic level of the second node, and a logic level of a fourth node to a third node;
a second NAND circuit that outputs a reverse logical product (NAND) of a logic level of the third node and the clock signal to the fourth node;
an inverter circuit that reverses logic of the third node and outputs the reversed logic to a fifth node; and
a OR circuit that outputs a logical sum (OR) of the clock signal and a logic level of the fifth node as the internal clock signal.

6. The flip-flop circuit according to claim 3,
wherein the pulse generation circuit includes:
a first inverter circuit that reverses logic of the first node and outputs the reversed logic to a fifth node;
a second inverter circuit that reverses logic of the second node and outputs the reversed logic to a sixth node;
a first NOR circuit that outputs a reverse logical sum (NOR) of a logic level of the fifth node, a logic level of the sixth node, and a logic level of the fourth node to a third node;
a third inverter circuit that reverses logic of the clock signal and outputs the reversed logic to a seventh node;
a second NOR circuit that outputs a reverse logical sum (NOR) of a logic level of the third node and a logic level of the seventh node to the fourth node; and
a AND circuit that outputs a logical product (AND) of a logic level of the third node and the clock signal as the internal clock signal.

7. The flip-flop circuit according to claim 3,
wherein the pulse generation circuit includes:
a first inverter circuit that reverses logic of the first node and outputs the reversed logic to a fifth node;
a second inverter circuit that reverses logic of the second node and outputs the reversed logic to a sixth node;
a first NOR circuit that outputs a reverse logical sum (NOR) of a logic level of the fifth node, a logic level of the sixth node, and a logic level of the fourth node to a third node;
a third inverter circuit that reverses logic of the clock signal and outputs the reversed logic to a seventh node;
a second NOR circuit that outputs a reverse logical sum (NOR) of a logic level of the third node and a logic level of the seventh node to the fourth node;
a fourth inverter circuit that reverses logic of the third node and outputs the reversed logic to an eighth node; and
a NAND circuit that outputs a reverse logical product (NAND) of a logic level of the seventh node and a logic level of the eighth node as the internal clock signal.

8. The flip-flop circuit according to claim 3,
wherein the pulse generation circuit includes:
a first NAND circuit that outputs a reverse logical product (NAND) of the clock signal, a logic level of the first node, a logic level of the second node, and a logic level of a third node to a fourth node;
a second NAND circuit that outputs a reverse logical product (NAND) of the clock signal and a logic level of the fourth node to the third node; and
an inverter circuit that reverses logic of the fourth node and outputs the reversed logic as the internal clock signal.

9. The flip-flop circuit according to claim 1,
wherein the first logic level is equal to the fourth logic level and the second logic level is equal to the third logic level.

10. The flip-flop circuit according to claim 9,
wherein the pulse generation circuit includes:
a first NAND circuit that outputs a reverse logical product (NAND) of a logic level of the first node, a logic level of the second node, and a logic level of a fourth node to a third node;
an inverter circuit that reverses logic of the clock signal and outputs the reversed logic to a fifth node;
a second NAND circuit that outputs a reverse logical product (NAND) of a logic level of the third node and a logic level of the fifth node to the fourth node; and
a NOR circuit that outputs a reverse logical sum (NOR) of the clock signal and a logic level of the third node as the internal clock signal.

11. The flip-flop circuit according to claim 9,
wherein the pulse generation circuit includes:
a first inverter circuit that reverses logic of the first node and outputs the reversed logic to a fifth node;
a second inverter circuit that reverses logic of the second node and outputs the reversed logic to a sixth node;
a first NOR circuit that outputs a reverse logical sum (NOR) of a logic level of the fifth node, a logic level of the sixth node, and a logic level of the fourth node to a third node;
a second NOR circuit that outputs a reverse logical sum (NOR) of a logic level of the third node and the clock signal to the fourth node;
a third inverter circuit that reverses logic of the third node and outputs the reversed logic to a seventh node; and
a third NOR circuit that outputs a reverse logical sum (NOR) of a logic level of the seventh node and the clock signal as the internal clock signal.

12. The flip-flop circuit according to claim 9,
wherein the pulse generation circuit includes:
a first inverter circuit that reverses logic of the first node and outputs the reversed logic to a fourth node;
a second inverter circuit that reverses logic of the second node and outputs the reversed logic to a fifth node;
a first NOR circuit that outputs a reverse logical sum (NOR) of the clock signal, a logic level of the fourth node, a logic level of the fifth node, and a logic level of a third node as the internal clock signal; and
a second NOR circuit that outputs a reverse logical sum (NOR) of the internal clock signal and the clock signal to the third node;

13. The flip-flop circuit according to claim 1,
wherein the input section includes:
a first first-conduction type transistor that is connected between a first power source line for supplying a first electric potential and the first node and receives the internal clock signal at a gate terminal;
a first second-conduction type transistor that is connected between the first node and a second power source line for supplying a second electric potential and receives the internal clock signal at a gate terminal; and
a second second-conduction type transistor that is connected between the first node and the second power source line in series to the first second-conduction type transistor and receives the data signal at a gate terminal.

14. The flip-flop circuit according to claim 13,
wherein an absolute value of a threshold voltage of the first first-conduction type transistor is smaller than an absolute value of a threshold voltage of at least one or more other first-conduction type transistor constructing the flip-flop circuit.

15. The flip-flop circuit according to claim 1,
wherein the control section includes:
an inverter circuit that reverses logic of the first node and outputs the reversed logic to a first control node;
a first second-conduction type transistor that is connected between the second node and the first control node and receives the internal clock signal at a gate terminal; and
a first first-conduction type transistor that is connected between a first power source line for supplying a first electric potential and the second node and receives the internal clock signal at a gate terminal.

16. The flip-flop circuit according to claim 15,
wherein the control section further includes:
a second first-conduction type transistor that is connected between the first power source line and the second node and has a gate terminal connected to the first node.

17. The flip-flop circuit according to claim 15,
wherein an absolute value of a threshold voltage of the first first-conduction type transistor is smaller than an absolute value of a threshold voltage of at least one or more other first-conduction type transistor constructing the flip-flop circuit.

18. The flip-flop circuit according to claim 1,
wherein the control section includes:
a first first-conduction type transistor that is connected between a first power source line for supplying a first electric potential and the second node and receives the internal clock signal at a gate terminal;
a first second-conduction type transistor that is connected between the second node and a second power source line for supplying a second electric potential and receives the internal clock signal at a gate terminal; and
a second second-conduction type transistor that is connected between the second node and the second power source line in series to the first second-conduction type transistor and has a gate terminal connected to the first node.

19. The flip-flop circuit according to claim 18,
wherein the control section further includes:
an inverter circuit that reverses logic of the first node and outputs the reversed logic to a first control node.

20. The flip-flop circuit according to claim 18,
wherein the control section further includes:
a second first-conduction type transistor that is connected between the first power source line and the second node and has a gate terminal connected to the first node.

21. The flip-flop circuit according to claim 18,
wherein an absolute value of a threshold voltage of the first first-conduction type transistor is smaller than an absolute value of a threshold voltage of at least one or more other first-conduction type transistor constructing the flip-flop circuit.

22. The flip-flop circuit according to claim 1,
wherein the output section includes:
a first first-conduction type transistor that is connected between a first power source line for supplying a first electric potential and an output node for outputting an output signal and has a gate terminal connected to the second node; and
a first second-conduction type transistor that is connected between the output node and a second power source line for supplying a second electric potential and receives a signal depending on a logic level of the first node at a gate terminal.

23. The flip-flop circuit according to claim 22,
wherein a signal inputted to a gate terminal of the first second-conduction type transistor is a reverse signal of a logic level of the first node.

24. The flip-flop circuit according to claim 1,
wherein the output circuit includes:
a first NAND circuit that outputs a reverse logical product (NAND) of a signal depending on a logic level of the first node and a first output signal as a second output signal; and
a second NAND circuit that outputs a reverse logical product (NAND) of a signal depending on a logic level of the second node and the second output signal as the first output signal.

25. A flip-flop circuit comprising:
a pulse generation circuit that receives a clock signal and outputs an internal clock signal; and
a plurality of latch circuits,
wherein each of the plurality of latch circuits includes:
an input section that receives a data signal and the internal clock signal, outputs a signal of a second logic level to a first node when the internal clock signal is at a first logic level, and outputs a signal of logic depending on a logic level of the data signal to the first node after the internal clock signal changes from the first logic level to the second logic level;
a control section that outputs a signal of the second logic level to a second node when the internal clock signal is at the first logic level, and outputs a signal of logic depending on a logic level of the first node to the second node when the internal clock signal is at the second logic level; and
an output section that outputs a signal of logic depending on a logic level of the first node and/or a logic level of the second node, and
wherein the pulse generation circuit changes the internal clock signal from the first logic level to the second logic level in response to a change of the clock signal from a third logic level to a fourth logic level and changes the internal clock signal from the second logic level to the first logic level after the first node or the second node changes from the second logic level to the first logic level in all of the plurality of latch circuits.
